(19) United States
(12) Patent Application Publication
(10) Pub. No.: US 2018/0269224 A1
(43) Pub. Date: Sep. 20, 2018

(54) MEMORY DEVICE

(71) Applicant: TOSHIBA MEMORY CORPORATION, Tokyo (JP)

(72) Inventor: Shun SHIMIZU, Yokkaichi Mie (JP)

(21) Appl. No.: 15/907,992

(22) Filed: Feb. 28, 2018

(30) Foreign Application Priority Data
Mar. 15, 2017 (JP) 2017-049984

(51) Int. Cl. H01L 27/11582; H01L 29/417; H01L 29/10; H01L 29/423; H01L 29/792; H01L 21/311; H01L 21/02; H01L 21/28; H01L 21/265

(52) U.S. Cl. CPC H01L 27/11582; H01L 29/41741; H01L 29/1037; H01L 29/4234; H01L 29/7926; H01L 27/11565; H01L 21/02532; H01L 21/02595; H01L 21/02636; H01L 21/28282; H01L 21/26513; H01L 21/31116

(57) ABSTRACT

According to one embodiment, a memory device includes a plurality of first electrode layers stacked over each other in a stacking direction, a pair of second electrode layers located over the plurality of first electrode layers in the stacking direction, a channel layer extending through the first and second electrode layers, and a charge storage layer between each first electrode layer and the channel layer. A thickness in the stacking direction of at least one of the second electrode layers being greater than a thickness in the stacking direction of any of the first electrode layers.

### CROSS-REFERENCE TO RELATED APPLICATION

This application is based upon and claims the benefit of priority from Japanese Patent Application No. 2017-049984, filed Mar. 15, 2017, the entire contents of which are incorporated herein by reference.

### FIELD

The present disclosure relates generally to a memory device.

### BACKGROUND

A memory device including memory cells arranged in a three-dimensional manner has been developed. For example, a NAND-type memory device includes a plurality of electrode layers stacked on a source layer, a channel layer formed extending through the plurality of electrode layers in the stacking direction, and a memory layer provided between the electrode layers and the channel layer. Memory cells are disposed at portions where the channel layer passes through an electrode layer, and are operated by potential differences between the channel layer and the electrode layers. In such a memory device, transistors are disposed at both ends of the memory cells arranged along the channel layer, and these transistors control the potential difference between the channel layer and the corresponding electrode layer. However, when the integration density of the memory device is increased, that is, when memory cells and electrode layers are reduced in size, on/off operations of these transistors may be delayed, resulting in a malfunction of the memory cell.

### DESCRIPTION OF THE DRAWINGS

FIG. 1 is a perspective view schematically illustrating a memory device according to an embodiment.

FIGS. 2A and 2B are schematic views illustrating the memory device according to the embodiment.

FIGS. 3A and 3B are schematic cross-sectional views illustrating a process of manufacturing the memory device according to the embodiment.

FIGS. 4A and 4B are schematic cross-sectional views illustrating a manufacturing process following the process of FIGS. 3A and 3B.

FIGS. 5A and 5B are schematic cross-sectional views illustrating a manufacturing process following the process of FIGS. 4A and 4B.

FIGS. 6A and 6B are schematic cross-sectional views illustrating a manufacturing process following the process of FIGS. 5A and 5B.

FIG. 7 is a schematic cross-sectional view illustrating a memory device according to a first modification of the embodiment.

FIG. 8 is a schematic cross-sectional view illustrating a memory device according to a second modification of the embodiment.

FIG. 9 is a schematic cross-sectional view illustrating a memory device according to a third modification of the embodiment.

FIG. 10 is a schematic cross-sectional view illustrating a memory device according to a fourth modification of the embodiment.

### DETAILED DESCRIPTION

In general, according to one embodiment, a memory device includes a plurality of first electrode layers stacked over each other in a stacking direction, a pair second electrode layers located over the plurality of first electrode layers in the stacking direction, a channel layer extending through the first and second electrode layers, and a charge storage layer between each of the first electrode layers and the channel layer, wherein a thickness in the stacking direction of at least one of the second electrode layers is greater than a thickness in the stacking direction of any of the first electrode layers.

Hereafter, exemplary embodiments will be described with reference to the accompanying drawings. The same components in the respective drawings are represented by like reference numerals, and the repeated detailed description thereof will be properly omitted, and description will be focused on different components. The drawings are schematically or conceptually illustrated, and the relationships between the thicknesses and widths of components and the size ratio of the components may be different from those in reality. Moreover, although the same portion is illustrated, the size or ratio of the portion may be differently set depending on the drawings.

The arrangement and structures of the components will be described with reference to the X-axis, Y-axis and Z-axis which are illustrated in the drawings. The X-axis, the Y-axis and the Z-axis cross one another at right angles, and indicate the X-direction, the Y-direction and the Z-direction, respectively. In some cases, the Z-direction may be set to extend from the top side of a feature, and the opposite direction of the Z-direction may be set to the bottom side of the feature.

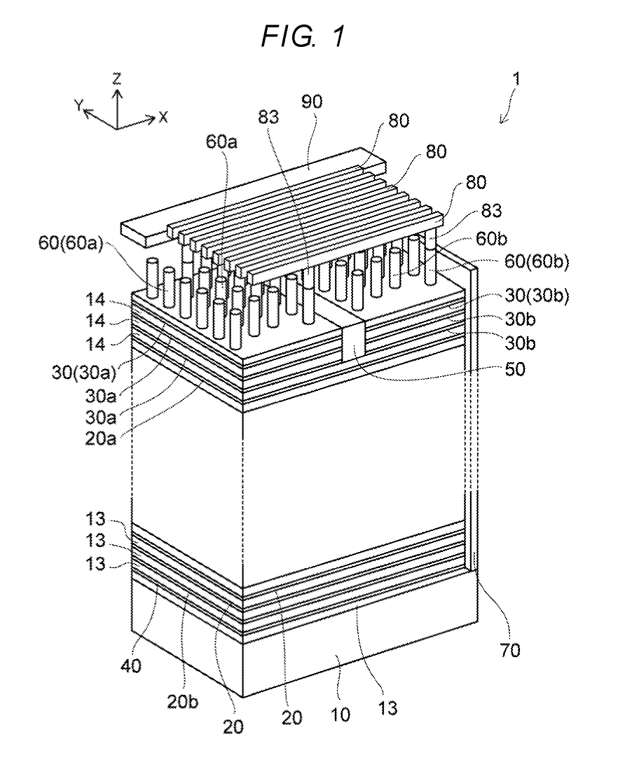

FIG. 1 is a perspective view schematically illustrating a memory device 1 according to an embodiment. The memory device 1 is a NAND-type nonvolatile memory device, for example, and includes memory cells arranged in a 3D manner.

As illustrated in FIG. 1, the memory device 1 includes a conductive layer (hereafter, referred to as a source layer 10), word lines 20, selection gates 30a, selection gates 30b, and selection gates 40. The selection gates 30a and 30b are arranged in parallel along the X-Y plane on the uppermost layer 20a of the word lines 20 on either side of an insulating layer 50. The selection gates 40 are disposed between the source layer 10 and the lowermost layer 20b of the word lines 20.

The source layer 10 is a P-type well provided in a silicon substrate, for example. Furthermore, the source layer 10 may be a polysilicon layer provided on the silicon substrate with an interlayer insulating layer (not specifically illustrated) interposed therebetween. The word lines 20 and the selection gates 30a, 30b, and 40 are metallic layers including tungsten (W), for example.

The word lines 20 and the selection gates 40 each have a two-dimensional layout, and are stacked on the surface of the source layer 10. Hereafter, the stacking direction of the word lines 20 may be referred to as a first direction, for example, the Z-direction. Between each of the word lines 20 adjacent to each other in the Z-direction, an insulating layer 13 is provided. The insulating layer 13 is a silicon oxide layer, for example.

The selection gates 30a and 30b are disposed on the plurality of word lines 20 while being spaced from each other in the X-direction, for example. Furthermore, two or more selection gates 30a and two or more selection gates 30b may be stacked over the uppermost layer 20a of the word lines 20. The insulating layer 13 is also provided between the uppermost word line layer 20a and the selection gate 30a and between the uppermost word line layer 20a and the selection gate 30b. An insulating layer 14 is provided between adjacent ones of the selection gates 30a adjacent to each other, and between adjacent ones of the selection gates 30b adjacent to each other, in the Z-direction, providing isolation therebetween.

The memory device 1 further includes an insulating layer 50 and a plurality of semiconductor layers 60. The insulating layer 50 is provided between the selection gate 30a and the selection gate 30b, and it extends in the Y-direction. The semiconductor layers 60 extend in the Z-direction through the word lines 20 and the selection gate 40. The semiconductor layer 60 is electrically connected to the source layer 10 at the bottom thereof. The semiconductor layers 60 include semiconductor layers 60a extending in the Z-direction through the selection gates 30a and semiconductor layers 60b extending in the Z-direction through the selection gates 30b.

Hereafter, the selection gates 30a and 30b will be referred to as selection gates 30, as long as the selection gates 30a and 30b are not separately described. Moreover, the semiconductor layers 60a and 60b will also be referred to as the semiconductor layers 60.

The memory device 1 includes a plurality of bit lines 80 and a source line 90 which are provided over the selection gates 30, for example. One of the semiconductor layers 60a and one of the semiconductor layers 60b are electrically connected to a common bit line 80. The bit lines 80 are thicker in the Z direction than the word lines 20. The semiconductor layer 60 is electrically connected to the bit line 80 through a contact plug 83. The source line 90 is electrically connected to the source layer 10 through a source contact 70. As illustrated in FIG. 1, the source contact 70 extends in the Y- and Z-direction along the side surfaces of the plurality of word lines 20 and the side surface of the selection gates 30.

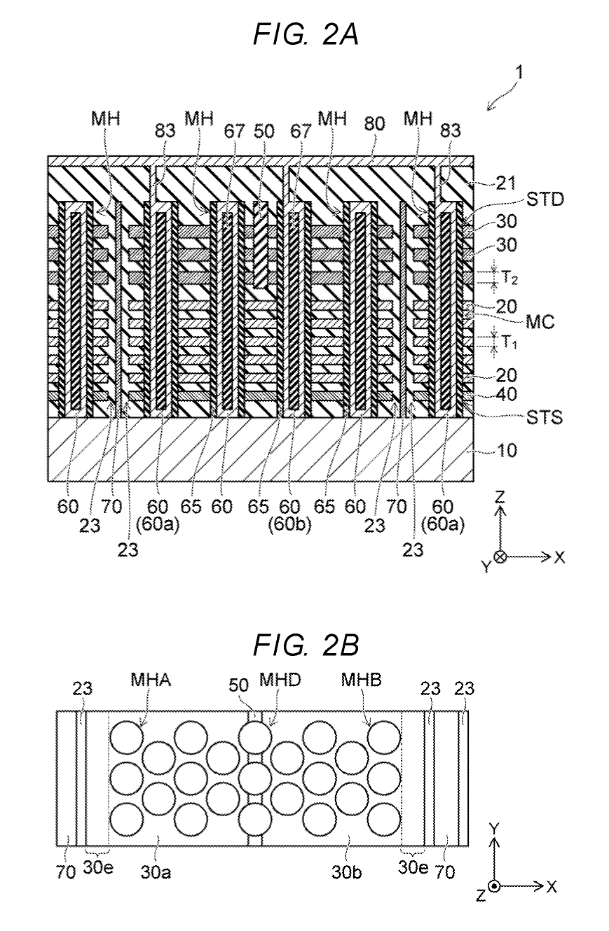

In FIG. 1, an interlayer insulating layer 21 provided between the selection gates 30 and the bit line 80 and an insulating layer 23 provided between the source contact 70 and the word lines 20 and the selection gates 30 and 40 are omitted (shown in FIG. 2A), in order to illustrate the structure of the memory device 1.

FIGS. 2A and 2B are schematic views illustrating a part of the memory device 1 according to the embodiment. FIG. 2A is a schematic view illustrating a part of a cross-section of the memory device 1 taken along the X-Z plane. FIG. 2B is a schematic plan view illustrating the upper surfaces of the selection gates 30a and 30b. Hereafter, the structure of the memory device 1 will be described in detail with reference to FIGS. 2A and 2B.

The memory device 1 includes a semiconductor layer 60, an insulating layer 65 and an insulating core 67 which are provided in a memory hole MH passing through the plurality of word lines 20 and the selection gates 30 in the Z-direction. The insulating core 67 extends in the Z-direction in the memory hole MH. The semiconductor layer 60 surrounds the side surface of the insulating core 67, while extending in the Z-direction along the insulating core 67. The insulating layer 65 is provided between the inner wall of the memory hole MH and the semiconductor layer 60, and extends in the Z-direction. The insulating layer 65 surrounds the side surface of the semiconductor layer 60.

The memory cells MC are thus formed at the respective portions where the semiconductor layer 60 passes through the word lines 20. In the insulating layer 65, portions between the semiconductor layer 60 and the word lines 20 function as charge storage units of the memory cells MC. The semiconductor layer 60 functions as a channel shared by the plurality of memory cells MC, and the word lines 20 function as control gates of the respective memory cells MC.

The insulating layer 65 has an ONO structure in which a silicon oxide layer, a silicon nitride layer and another silicon oxide layer are stacked on the inner wall of the memory hole MH, for example. The portions of the insulating layer 65 at the memory cells MC serves to retain charges injected from the semiconductor layer 60, and discharge the charges to the semiconductor layer 60 at the memory cells MC.

Furthermore, selection transistors STD and STS are formed at portions where the semiconductor layer 60 passes through the selection gates 30 and 40. The semiconductor layer 60 functions as the channel for the selection transistors STD and STS, and the selection gates 30 and 40 function as gate electrodes of the selection transistors STD and STS, respectively. The part of the insulating layer 65 located between the semiconductor layer 60 and the selection gate 30 and between the semiconductor layer 60 and the selection gate 40 functions as a gate insulating film.

The source contact 70 is provided between the word lines 20 adjacent to each other, between the selection gates 30 adjacent to each other, and between the selection gates 40 adjacent to each other, in the X-direction. The source contact 70 is a plate-shaped metallic layer extending in the Y- and Z-axis directions, for example, and electrically connects the source layer 10 and the source line 90 (refer to FIG. 1). The source contact 70 is electrically insulated from the word lines 20 and the selection gates 30 and 40 by the insulating layer 23.

The selection gates 30 disposed over the word lines 20 are divided by the insulating layer 50. The insulating layer 50 is a silicon oxide layer, for example, and extends in the Y-direction. The selection gates 30 are divided into the selection gates 30a and 30b, for example (refer to FIG. 1). Thus, the selection transistor STD using a selection gate 30a as the gate electrode can control the potential of the semiconductor layer 60a formed through the word lines 20 and the selection gate 30a, and the selection transistor STD using the selection gate 30b as the gate electrode can control the potential of the semiconductor layer 60b formed through the word lines 20 and the selection gates 30b. Therefore, both of the semiconductor layers 60a and 60b can be connected to one bit line 80.

For example, when the insulating layer 50 is not provided, only one of the semiconductor layers 60a and 60b is connected to one bit line 80. That is, the providing of the insulating layer 50 can halve the number of required bit lines 80, and reduces the circuit scale of the sense amplifier connected to the bit lines 80.

As illustrated in FIG. 2B, the insulating layer 50 extends in the Y-direction, and divides the selection gates 30 into the selection gates 30a and 30b. The selection gates 30a and 30b have memory holes MHA and MHB provided therein, respectively. Each of the memory holes MHA and MHB includes the semiconductor layer 60, the insulating layer 65 and the insulating core 67. Furthermore, a memory hole MHD may be formed to divide the insulating layer 50. The memory hole MHD is formed to increase an exposure margin in a photolithography process for forming the memory hole MH, for example. Therefore, the semiconductor layer 60 provided in the memory hole MHD is not connected to the bit line 80, and does not operate the memory cells MC.

Ends of the selection gates 30a to 30b in the Y-direction are electrically connected to a row decoder (not illustrated). The row decoder supplies a gate potential to the selection transistor STD through the selection gates 30a and 30b. Since the selection gates 30a and 30b extend in the Y-direction, for example, each of the selection gates 30a and 30b may have as low resistance as possible, in order to supply a uniform potential to all of the selection transistors STD sharing the selection gate.

As illustrated in FIG. 2B, the selection gates 30a and 30b have the plurality of memory holes MHA and MHB provided therein. Thus, edge portions 30e of the selection gates 30a and 30b mainly contribute to electrical conduction. For example, since the word line 20 is not divided by the insulating layer 50, both edge portions of the word line 20 in the X-direction contribute to electrical conduction. However, since only one edge portion 30e of each of the selection gates 30a and 30b contributes to electrical conduction, the electrical resistance of the selection gate becomes twice as large as that of a word line 20.

The increase in resistance of a selection gate 30 delays a rise of the gate potential, for example. Therefore, when data are written to a memory cell MC, the timing to turn off the selection transistor STD of a memory string which does not include the selected memory cell may be delayed. In this case, a write error may occur during the write operation for the memory cell MC.

For this reason, the memory device 1 according to the embodiment has a structure in which the thickness T₂ of the selection gates 30 in the Z-direction is larger than the thickness T₁ of the word lines 20 in the Z-direction. For example, when the thickness T₂ of a selection gate 30 is twice as large as the thickness T₁ of a word line 20, the resistance value of the selection gate 30 in the Y-direction is substantially equal to the resistance value of the word line 20 in the Y-direction, and the delay of the selection transistor STD can be removed. Furthermore, in order to easily process the memory hole MH described later, it is desirable that the thickness T₂ of the selection gate 30 is not set to a larger value than needed. For example, the thickness T₂ of the selection gates 30 may be set to twice or less the thickness T₁ of the word lines 20, preferably 1.5 times or less the thickness T₁ of the word lines 20. For example, the thickness T₂ of the selection gates 30 may be set to 1.2 times the thickness T₁ of the word lines 20.

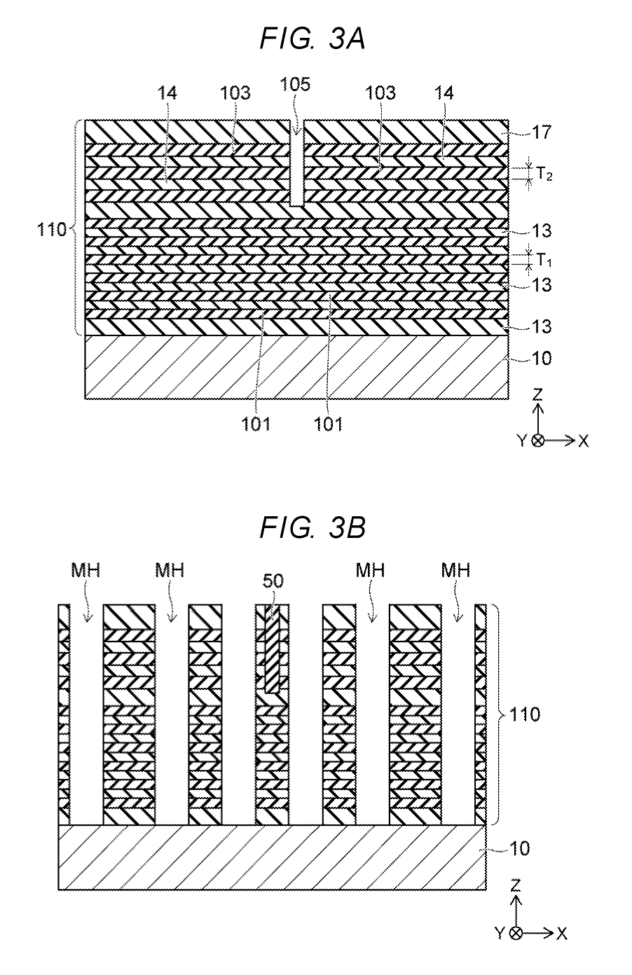

Next, a method for manufacturing the memory device 1 according to the embodiment will be described with reference to FIGS. 3A to 6B. FIGS. 3A to 6B are schematic cross-sectional views illustrating a process of manufacturing the memory device 1.

As illustrated in FIG. 3A, a stacked body 110 is formed on a source layer 10. The stacked body 110 includes insulating layers 13, 14 and 17 and sacrificial layers 101 and 103, for example. The insulating layers 13, 14 and 17 are silicon oxide layers, for example. The sacrificial layers 101 and 103 are silicon nitride layers, for example.

The insulating layers 13 and the sacrificial layers 101 are alternately stacked over the source layer 10. The sacrificial layer 101 has a thickness T₁ in the Z-direction. The sacrificial layers 103 and the insulating layers 14 are alternately stacked over the uppermost layer of the insulating layers 13. The stacked body 110 includes two or more sacrificial layers 103 stacked therein. The sacrificial layer 103 has a thickness T₂ in the Z-direction. The insulating layer 17 is provided on the uppermost layer of the sacrificial layers 103.

Moreover, a groove 105 is formed from the upper surface of the stacked body 110 so as to divide the insulating layers 14 and 17 and the sacrifice layers 103. The groove 105 extends in the Y-direction.

As illustrated in FIG. 3B, an insulating layer 50 and memory holes MH are formed in the stacked body 110. The insulating layer 50 is a silicon oxide layer, for example, and formed so as to fill the groove 105. The memory hole MH is formed by anisotropic RIE (Reactive Ion Etching), for example, and has a depth from the upper surface of the stacked body 110 to the source layer 10.

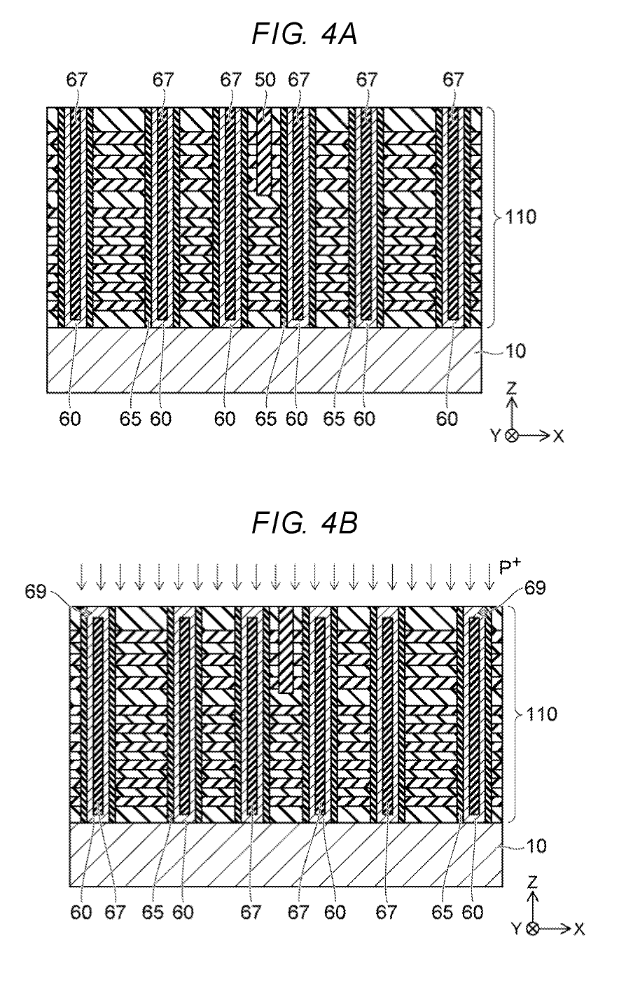

As illustrated in FIG. 4A, a semiconductor layer 60, an insulating layer 65 and an insulating core 67 are formed in the memory hole MH. The semiconductor layer 60 is a polysilicon layer, for example, and electrically connects to the source layer 10 at the bottom thereof.

For example, a first silicon oxide layer, a silicon nitride layer and a second silicon oxide layer are sequentially stacked to cover the inner surface of the memory hole MH, and the insulating layer 65 is formed. While a continuous portion of the insulating layer 65 formed on the inner wall of the memory hole MH is left, the portion thereof formed on the bottom surface of the memory hole MH is selectively removed. Then, the semiconductor layer 60 is formed so as to cover the inner surface and bottom of the memory hole MH, and the insulating core 67 is deposited in the memory hole MH.

As illustrated in FIG. 4B, a drain region 69 is formed on the insulating core 67 in the memory hole MH. The drain region 69 is formed through a process of etching back the upper portion of the insulating core 67 and depositing amorphous silicon in the resultant space. Furthermore, phosphorous (P) is ion-implanted as an N-type impurity into the drain region 69. The drain region 69 may include one or more impurity elements from among arsenic (As), phosphorous (P), boron (B) and gallium (Ga).

In the embodiment, the thickness T₂ of the selection gates 30 is set to a larger value than the thickness T₁ of the word lines 20. For this reason, the characteristic of the selection transistor STD, such as a roll-off characteristic, can be improved. As a result, the dose and implantation energy of the impurity implanted into the drain region 69 can be reduced, and the manufacturing cost can be reduced.

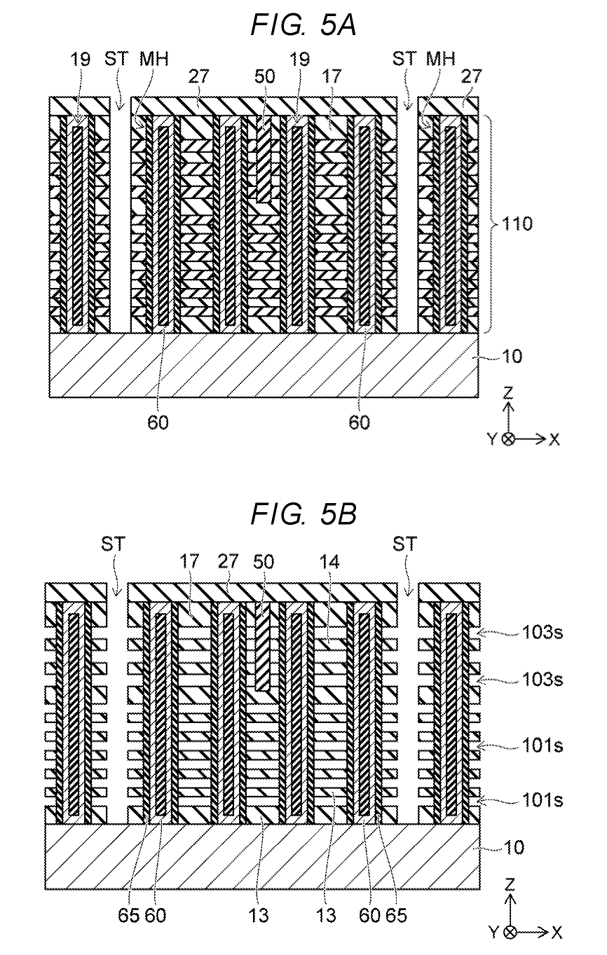

As illustrated in FIG. 5A, an insulating layer 27 is formed to cover the memory hole MH and the upper surface of the insulating layer 17. The insulating layer 27 is a silicon oxide layer, for example. Continuously, a slit ST is formed to have a depth from the upper surface of the insulating layer 27 to the source layer 10. The slit ST extends in the Y-direction, for example, and divides the stacked body 110 into a plurality of portions.

As illustrated in FIG. 5B, the sacrifice layers 101 and 103 are selectively removed through the slit ST. For example, an etching solution, such as hot phosphoric acid, is supplied through the slit ST, in order to selectively remove the sacrificial layers 101 and 103 while the insulating layers 13, 14, 17 and 27 remain in place.

Through spaces 101s and 103s formed by removing the sacrifice layers 101 and 103, the insulating layer 65 is partially exposed. The insulating layers 13 and 14 are supported by the semiconductor layer 60, the insulating layer 65 and the insulating core 67 which are formed in the memory hole MH. Therefore, the open spaces 101s and 103s are maintained.

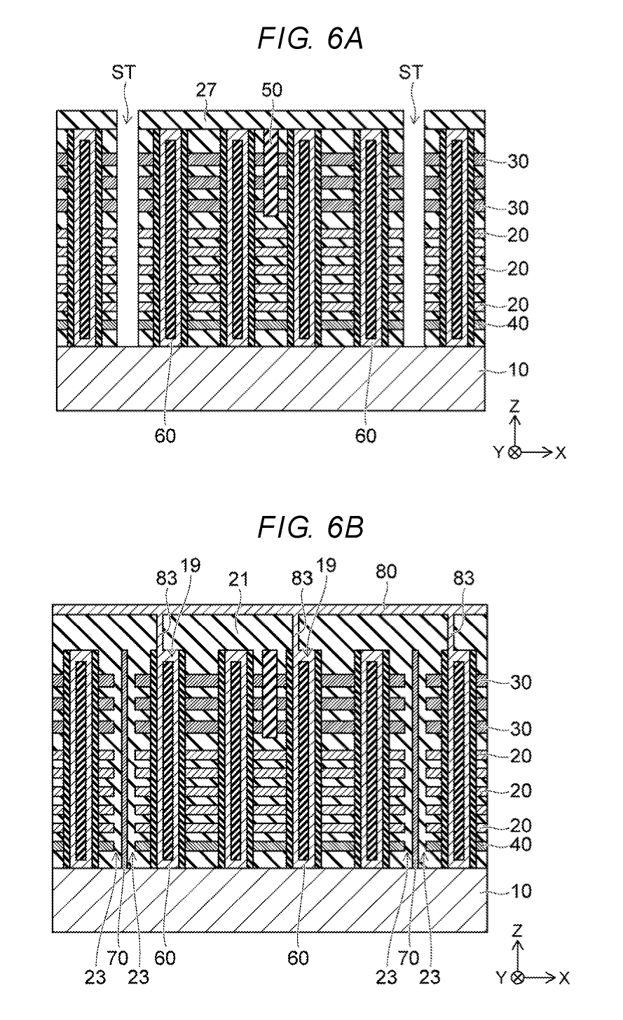

As illustrated in FIG. 6A, word lines 20 and selection gates 30 and 40 are formed in the spaces 101s and 103s. The word lines 20 and the selection gates 30 and 40 are formed through a process of depositing a metallic layer including tungsten in the spaces 101s and 103s using CVD (Chemical Vapor Deposition), for example.

When the sacrificial layer 103 is formed to have an excessively large thickness of T₂, the depth of the space 103s may be widened. In this case, even after a portion to be used as the word line 20 is formed in the space 101s, a cavity may remain in the space 103s. As a result, a void may be formed in the selection gate 30 formed in the space 103s. Therefore, the thickness T₂ of the sacrifice layer 103 cannot be set to a larger value than needed. For example, the thickness T₂ of the sacrifice layer 103 (that is, the thickness T₂ of the selection gates 30) may be set to twice or less the thickness T₁ of the word lines 20, such that the resistance of the selection gates 30 is substantially equal to the resistance of the word lines 20. More desirably, the thickness T₂ of the selection gates 30 may be set to 1.5 times or less the thickness T₁ of the word lines 20. For example, the thickness T₂ of the selection gates 30 may be set to 1.2 times the thickness T₁ of the word lines 20.

As illustrated in FIG. 6B, an insulating layer 23 and a source contact 70 are then formed in the slit ST. An interlayer insulating layer 21 and a bit line 80 are formed to continuously cover the insulating layer 27. The bit line 80 is formed on the interlayer insulating layer 21, and electrically connected to the semiconductor layer 60 through a contact plug 83 provided in the interlayer insulating layer 21.

A contact hole is formed to communicate with the selection gate 30, and a contact plug is formed in the contact hole. In this case, when the selection gate 30 is formed with a large thickness, the penetration by the contact hole can be avoided. That is, it is possible to increase a process margin when the contact hole is formed.

In the embodiment, since the thickness T₂ of the selection gates 30 is set to a larger value than the thickness T₁ of the word lines 20, the operation speed of the selection transistor STD can be improved, which makes it possible to prevent a write error during a write operation for a memory cell MC.

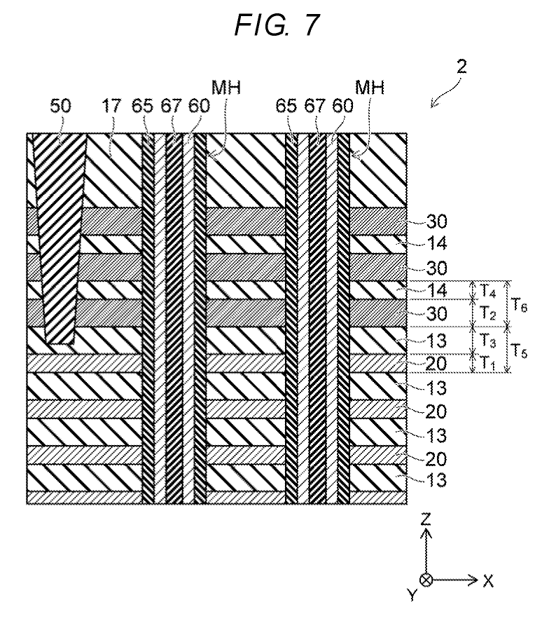

Next, memory devices 2 to 5 according to modifications of the embodiment will be described with reference to FIGS. 7 to 10.

FIGS. 7 to 10 are schematic cross-sectional views illustrating parts of the memory devices 2 to 5.

FIG. 7 is a schematic cross-sectional view illustrating the memory device 2 according to the first modification of the embodiment. In the memory device 2, three selection gates 30 are stacked over the word lines 20. The thickness T₂ of the selection gates 30 is set to a larger value than the thickness T₁ of the word lines 20. The memory device 2 has a structure in which a thickness T6 in the Z-direction, obtained by adding up the thickness T₂ of a selection gate 30 and the thickness T₄ of the adjacent insulating layer 14, is substantially equal to a thickness T₅ in the Z-direction, obtained by adding up the thickness T₁ of a word line 20 and the thickness T₃ of an adjacent insulating layer 13.

Therefore, the memory hole MH and the groove 105 can be formed through the same etching condition as the case in which the sacrifice layers 101 and 103 have the same thickness and the insulating layers 13 and 14 have the same thickness. That is, the level of difficulty in an etching process for the memory hole MH and the groove 105 is not changed.

In this example, the thickness T₄ of the insulating layer 14 is smaller than the thickness T₃ of the insulating layer 13, and the insulation breakdown voltage is lowered. However, since the same potential is supplied to the plurality of selection gates 30, the operation of the memory device 1 is not affected.

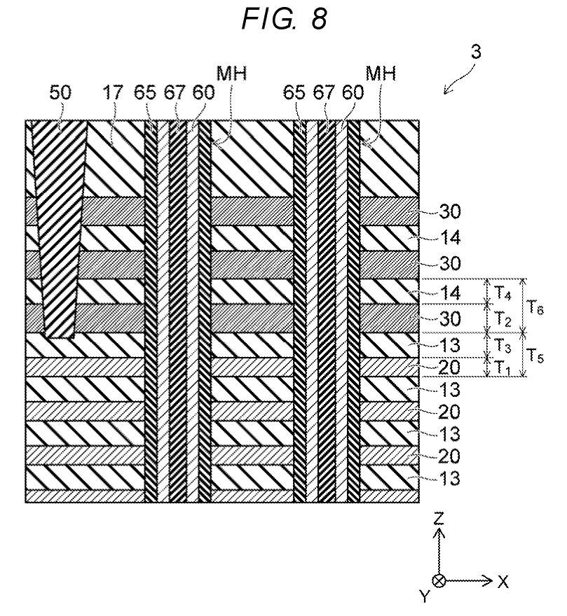

FIG. 8 is a schematic cross-sectional view illustrating the memory device 3 according to the second modification of the embodiment. In the memory device 3, three selection gates 30 are stacked over the word lines 20. The thickness T₂ of the selection gates 30 is greater than the thickness T₁ of the word lines 20. Moreover, the thickness T₄ of the insulating layer 14 is substantially the same value as the thickness T₃ of the insulating layer 13.

In this example, since the total thickness of the three selection gates 30 and the insulating layers 14 therebetween is increased, a distance between the drain region 19 and the uppermost layer of the word lines 20 is increased. Therefore, it is possible to prevent a write error during a write operation for the memory cell MC, which may be caused by GIDL (Gate Induced Drain Leakage). Furthermore, the cut-off characteristic margin of the selection transistor STD is improved. For example, a margin for a Z-direction depth variation of the N-type impurity in the drain region 19 can be improved. Furthermore, since the thickness T6 is larger than the thickness T₅, the roll-off characteristic of the selection transistor STD can be improved.

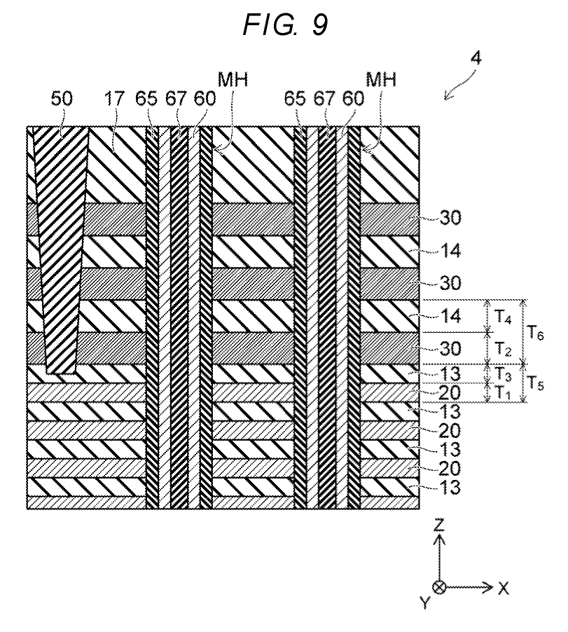

FIG. 9 is a schematic cross-sectional view illustrating the memory device 4 according to the third modification of the embodiment. In the memory device 4, three selection gates 30 are stacked over the uppermost word line 20. The thickness T₂ of the selection gates 30 is set to a larger value than the thickness T₁ of the word lines 20. Furthermore, the thickness T₄ of the insulating layer 14 is set to a larger value than the thickness T₃ of the insulating layer 13.

In this example, since the total thickness of the three selection gates 30 and the insulating layers 14 therebetween are increased, a distance between the drain region 19 and the uppermost layer of the word lines 20 is increased. Therefore, it is possible to prevent a write error during a write operation for the memory cell MC, which may be caused by GIDL. Moreover, the cut-off characteristic margin of the selection transistor STD can be improved. For example, a margin for a Z-direction depth variation of the N-type impurity in the drain region 19 can be improved. Furthermore, since the thickness T6 is larger than the thickness T₅, the roll-off characteristic of the selection transistor STD can be improved. Furthermore, the increase of the thickness T₄ of the insulating layer 14 can prevent deflection of the insulating layer 14 after the sacrifice layer 103 is removed. Therefore, the margin of the space 103s formed by removing the sacrifice layer 103 can be increased (refer to FIG. 5B).

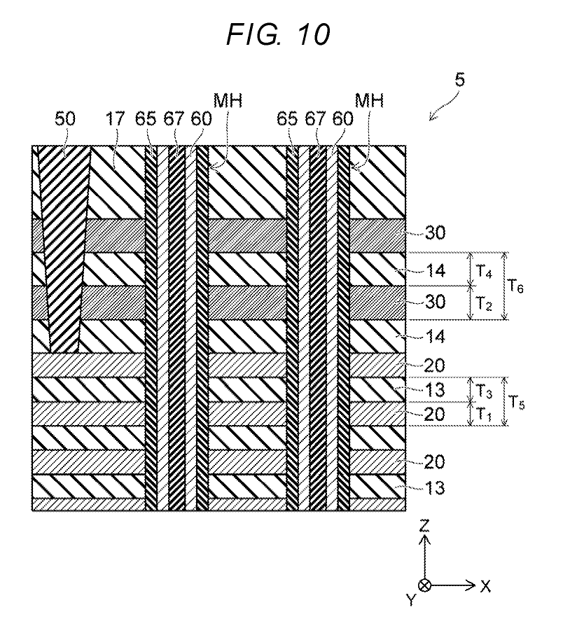

FIG. 10 is a schematic cross-sectional view illustrating the memory device 5 according to the fourth modification of the embodiment. In the memory device 5, two selection gates 30 are stacked over the word line 20. The thickness T₂ of the selection gates 30 is set to a larger value than the thickness T₁ of the word lines 20. Furthermore, the sum of the thickness 2T₂ of two selection gates 30 and the thickness 2T₄ of two insulating layers 14 is larger than the sum of the thickness 2T₁ of two word lines 20 and the thickness 2T₃ of two insulating layers 13 (2T₂+2T₄>2T₁+2T₃). Furthermore, the sum of the thickness 2T₂ of two selection gates 30 and the thickness 2T₄ of two insulating layers 14 is less than or equal to the sum of the thickness 3T₁ of three word lines 20 and the thickness 3T₃ of the three insulating layer 13 (2T₂+2T₄<3T₁+3T₃)

Therefore, the level of difficulty in the etching process for the memory hole MH and the groove 105 can be reduced, compared to when three selection gates 30 are stacked. Moreover, the total thickness 2T₂ of the selection gates 30 can be increased, and the pinch-off characteristic can be improved. For example, deflection after the removing of the sacrifice layers 103 is not increased even at the same total thickness, and the reduction in gate resistance of the selection transistor STD can prevent a write error.

The present embodiments are only examples, and the present disclosure is not limited thereto. For example, the number of selection gates 30 stacked in the memory device may be set to four or more. Furthermore, the word line 20 and the selection gates 30 and 40 are not limited to tungsten, but may be formed of a polysilicon layer or a metallic layer including titanium. Moreover, the insulating layers 13 and 14 are not limited to a silicon oxide layer, but may be formed of a silicon nitride layer or aluminum oxide layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device, comprising:
a plurality of first electrode layers stacked over each other in a stacking direction;
a pair of second electrode layers located over the plurality of first electrode layers in the stacking direction;
a channel layer extending through the first and second electrode layers; and
a charge storage layer between each first electrode layer and the channel layer, wherein
a thickness in the stacking direction of at least one of the second electrode layers is greater than a thickness in the stacking direction of any of the first electrode layers.

2. The memory device according to claim 1, further comprising:
a first insulating layer between two adjacent first electrode layers in the stacking direction; and
a second insulating layer between the pair of second electrode layers in the stacking direction, wherein
a thickness in the stacking direction of the second insulating layer is substantially equal to a thickness in the stacking direction of the first insulating layer.

3. The memory device according to claim 1, further comprising:
a first insulating layer between two adjacent first electrode layers in the stacking direction; and
a second insulating layer between the pair of second electrode layers in the stacking direction, wherein
a thickness in the stacking direction of the second insulating layer is less than a thickness in the stacking direction of the first insulating layer.

4. The memory device according to claim 1, further comprising:
a first insulating layer between two adjacent first electrode layers in the stacking direction; and
a second insulating layer between the pair of second electrode layers in the stacking direction, wherein
a thickness in the stacking direction of the second insulating layer is greater than a thickness in the stacking direction of the first insulating layer.

5. The memory device according to claim 1, further comprising:
a second pair of second electrode layers stacked over the plurality of first electrode layers in the stacking direction, wherein
the second pair of second electrode layers does not extend over the first pair of second electrode layers.

6. The memory device according to claim 5, further comprising:
at least two third electrode layers located over the plurality of first electrode layers in the stacking direction, each extending in a direction crossing over the first and second pairs of second electrode layers; and
an insulator between the second electrode layers and the third electrode layers, wherein
a thickness of the third electrode layer in the stacking direction is larger than a thickness of a first electrode layer in the stacking direction.

7. The memory device according to claim 1, wherein a thickness of the first pair of second electrode layers in the stacking direction is greater than or equal to 1.2 times a thickness in the stacking direction of a first electrode layer.

8. The memory device according to claim 7, wherein the thickness of the first pair of second electrode layers in the stacking direction is less than or equal to 1.5 times a thickness in the stacking direction of a first electrode layer.

9. A memory device, comprising;
a plurality of first electrode layers stacked one over the other in a first direction;
a plurality of second electrode layers stacked one over each other in the first direction and located over the plurality of first electrode layers; and
an insulating layer extending inwardly of the plurality of second electrode layers and bifurcating each second electrode layer into a first portion and a second portion, wherein a thickness of the second electrode layers in the first direction is greater than a thickness of the first electrode layers in the first direction.

10. The memory device according to claim 9, further comprising:
a conductor extending in the first direction through the plurality of first electrodes and second electrodes; and
a charge storage layer located between the conductor and the plurality of first electrode layers.

11. The memory device of claim 10, further comprising:
a plurality of first insulating layers between adjacent first electrode layers in the plurality of first electrode layers; and
a plurality of second insulating layers between adjacent second electrode layers in the plurality of second electrode layers.

12. The memory device according to claim 11, wherein a thickness of each second insulating layer in the first direction is equal to a thickness of each first insulating layer in the first direction.

13. The memory device according to claim 11, wherein a thickness of each second insulating layer in the first direction is greater than a thickness of each first insulating layer in the first direction.

14. The memory device according to claim 11, wherein a thickness of each second electrode layer in the first direction is less than or equal to 1.5 times a thickness in the first direction of each first electrode layer.

15. The memory device according to claim 14, wherein the thickness of the each second electrode layer in the first direction is greater than or equal to 1.2 times the thickness in the first direction of each first electrode layer.

16. The memory device according to claim 9, further comprising:
two or more third electrode layers located over the first electrode layers, each third electrode layer extending in a direction crossing over the first and second portions of second electrode layers; and
an insulator between the second electrode layers and the third electrode layer, wherein a thickness of the third electrode layers in the first direction is larger than the thicknesses of the first electrode layers in the first direction.

17. A memory device, comprising:
a plurality of first electrodes located one over the other, wherein each adjacent pair of first electrodes in the plurality is separated by a first insulating layer;
at least one second electrode located over the plurality first electrodes;
a channel extending through at least a portion of the plurality of first electrodes and through the at least one second electrode; and
a charge storage layer located between the channel and each first electrode at position at which the channel penetrates the first electrode, wherein
the second electrode is thicker than any first electrode in the plurality of first electrodes.

18. The memory device according to claim 17, wherein the thickness of the second electrode is greater than or equal to 1.2 times a thickness of a first electrode in the plurality and less than or equal to 1.5 times the thickness of the first electrode in the plurality.

19. The memory device according to claim 17, wherein
the at least one second electrode comprises at least two second electrode portions separated by a second insulating layer, and
a thickness of the second insulating layer is greater than a thickness of a first insulating layer disposed between adjacent first electrodes in the plurality.

20. The memory device according to claim 17, further comprising:
at least two third electrode layers located over the at least one second electrode layer and the plurality of first electrode layers; and
an insulator provided between the at least one second electrode layer and the at least two third electrode layers, wherein
a thickness of a third electrode layer is greater than a thickness of any one of the first electrodes in the plurality.
